(19) United States
(12) Patent Application Publication
(10) Pub. No.: US 2022/0199597 A1
(43) Pub. Date: Jun. 23, 2022

(54) DISPLAY DEVICE

(71) Applicants: INTERFACE TECHNOLOGY (CHENGDU) CO., LTD., Chengdu City (CN); INTERFACE OPTOELECTRONICS (SHENZHEN) CO., LTD, Shenzhen City (CN); GENERAL INTERFACE SOLUTION LIMITED, Miaoli County (TW)

(72) Inventors: YA CHU HSU, Shenzhen City (CN); PO LUN CHEN, Shenzhen City (CN); CHUN TA CHEN, Shenzhen City (CN); PO CHING LIN, Shenzhen City (CN); CHIA-MING FAN, Shenzhen City (CN); PING HSIANG KAO, Shenzhen City (CN); CHIEN YU HUANG, Shenzhen City (CN)

(21) Appl. No.: 17/158,422

(22) Filed: Jan. 26, 2021

(30) Foreign Application Priority Data
Dec. 22, 2020 (CN) 202011526800.9

(51) Int. Cl. H01L 25/16; H01L 23/00

(52) U.S. Cl. CPC H01L 25/167; H01L 24/09; H01L 2224/09181; H01L 2924/1426; H01L 2224/08225; H01L 2924/12041; H01L 2224/08145

(57) ABSTRACT

A display device integrates a driver IC and a micro-LED into a micro-LED module to encapsulate the related circuitry together. The stretchable conductive material is disposed on the flexible substrate to effectively reduce the problem of rising resistances caused by stretching. Specifically, both the driver IC and the micro-LED are disposed on the substrate, or the driver IC is served as a substrate to carry the micro-LEDs to encapsulate into the micro-LED module. Then, the stretchable conductive material is utilized to dispose on the flexible substrate to form the display device adapted for non-plane surface.

This application claims priority of Application No. 202011526800.9 filed in Main land China (P.R.C.) on 22 Dec. 2020 under 35 U.S.C. § 119; the entire contents of all of which are hereby incorporated by reference.

### BACKGROUND OF THE INVENTION

### Field of the Invention

The present invention relates to the technologies of the micro light-emitting diode (micro-LED) display, and more particularly, to a display device that integrates a driver integrated circuit (IC) and the micro-LEDs, which is suitable for non-planar light-emitting display devices.

### Description of the Prior Art

The micro-LED display technology is a new generation of display technology following the organic LED (OLED) technology. A large number of domestic and foreign manufacturers are ambitious in the development of the micro-LED which shows its market prospects are highly promising. The most noticeable advantage of the micro-LED display panel is that the size thereof is reduced down to approximately one percent of the traditional LED size, and therefore both the size and pixel spacing are reduced to the micron level. In addition, and each point-pixel can be controlled in an addressed manner and emit light individually, making the entire module downsized and providing the characteristics of high brightness, low power consumption, ultra-high resolution and color saturation, etc.

With the diversification of electronic products, non-planar electronic products have been seen in both the touch device or display fields. In order to achieve curved or even arbitrary shapes, it is necessary to use techniques such as injection molding, thermo-press molding, thermoplastic molding, etc. Among the above techniques, the thermoplastic molding is more suitable to be applied on products with wires or mounted with electronic components. However, stretching effects are introduced during the molding process, which may cause destruction on the conductive materials or components on the substrate, resulting in malfunction of the products. Therefore, how to reduce the risk of failure has become an important issue.

On the other hand, regarding the application of non-planar displays, applications that combine the OLED with a flexible substrate are commonly seen in recent years. However, a flexible OLED display only allows being bent or flexed, because the stretching process might damage components and cracks the water-blocking inorganic encapsulation layer, making it difficult to achieve curved applications.

Aiming to solve the above-mentioned obstacles, the present invention proposes a display device to solve the above problems.

### SUMMARY OF THE INVENTION

The main objective of the present invention is to provide a display device that utilizes a driver IC and a micro-LED to be integrated into a micro-LED module. Therefore, the display device constituted by it can be applied to non-planar electronic devices.

Another object of the present invention is to provide a display device. Through the integration of the micro-LED and the driver IC, the related control circuitry can be encapsulated together, and then the stretchable conductive material can be used on the flexible substrate so as to effectively mitigate the problem of rising resistances caused by stretching.

In order to achieve the above objective, the present invention provides a display device including a flexible substrate and a plurality of micro-LED modules. The micro-LED modules are disposed on one side of the flexible substrate via a stretchable conductive material, and each of the micro-LED modules includes at least one substrate with a circuit layer disposed thereon, at least one micro-LED disposed on the circuit layer of the substrate to form an electrical connection with the circuit layer, and a driver integrated circuit (IC) disposed on the circuit layer of the substrate and forming an electrical connection with the circuit layer.

In an embodiment of the present invention, the micro-LED is a red micro-LED, a green micro-LED or a blue micro-LED.

In an embodiment of the present invention, the flexible substrate comprises a thin film layer and a formable film disposed on the thin film layer.

In an embodiment of the present invention, the stretchable conductive material is composed of an electrically conductive metal, an electrically conductive glue, or a combination thereof.

In an embodiment of the present invention, the micro-LED module further comprises a common cathode disposed on the circuit layer of the substrate and forming an electrical connection with the circuit layer.

In an embodiment of the present invention, the micro-LED is disposed on the circuit layer of the substrate via a bonding pad, and forms an electrical connection with the circuit layer.

In an embodiment of the present invention, another side of the substrate has at least one bonding pad disposed on the stretchable conductive material of the flexible substrate, and makes the side of the circuit layer of the substrate be an emission side.

In an embodiment of the present invention, the micro-LED is a vertical micro-LED, and each of two sides of the vertical micro-LED has a metal electrode, and wherein the vertical micro-LED is disposed on the circuit layer of the substrate via one of the metal electrodes to form an electrical connection with the circuit layer.

In an embodiment of the present invention, the micro-LED module further comprises a driver IC bonding pad. The driver IC bonding pad is disposed on the circuit layer of the substrate, and is electrically connected to the circuit layer and the driver IC.

In an embodiment of the present invention, the driver IC comprises another driver IC bonding pad to be disposed on the stretchable conductive material of the flexible substrate, and the other metal electrode of the vertical micro-LED is disposed on the stretchable conductive material of the flexible substrate.

In an embodiment of the present invention, the flexible substrate is a transparent substrate to serve as an emission side.

In an embodiment of the present invention, the driver IC bonding pad is formed by coating a metal layer on a thickened material.

In an embodiment of the present invention, the thickened material is an electrically conductive glue or a photoresist material.

In addition, the present invention also provides a display device, which includes a flexible substrate and a plurality of micro-LED modules. The plurality of micro-LED modules are disposed on one side of the flexible substrate via a stretchable conductive material. Each of the micro-LED modules includes at least one driver IC and at least one micro-LED. The micro-LED is disposed on the driver IC and is electrically connected to the driver IC.

In an embodiment of the present invention, the micro-LED is a red micro-LED, a green micro-LED or a blue micro-LED.

In an embodiment of the present invention, the flexible substrate comprises a thin film layer and a formable film disposed on the thin film layer.

In an embodiment of the present invention, the stretchable conductive material is composed of an electrically conductive metal, an electrically conductive glue or a combination thereof.

In an embodiment of the present invention, the micro-LED is disposed on a bonding pad of the driver IC via a bonding pad to form an electrical connection with the driver IC.

In an embodiment of the present invention, another side of the driver IC has at least one bonding pad disposed on the stretchable conductive material of the flexible substrate.

In an embodiment of the present invention, the micro-LED is a vertical micro-LED, and each of two sides of vertical micro-LED has a metal electrode. The vertical micro-LED is disposed on a bonding pad of the driver IC via one of the metal electrodes to form an electrical connection with the driver IC.

In an embodiment of the present invention, the driver IC has a driver IC bonding pad disposed thereon to form an electrical connection with the driver IC.

In an embodiment of the present invention, the driver IC comprises another driver IC bonding pad to be disposed on the stretchable conductive material of the flexible substrate, and the other metal electrode of the vertical micro-LED is disposed on the stretchable conductive material of the flexible substrate.

In an embodiment of the present invention, the flexible substrate is a transparent substrate to serve as a emission side.

In an embodiment of the present invention, the driver IC bonding pad is formed by coating a metal layer on a thickened material.

In an embodiment of the present invention, the thickened material is an electrically conductive glue or a photoresist material.

The display device provided by the present invention integrates a driver IC and micro-LEDs into a micro-LED module, which utilizes the driver IC and the micro-LEDs to be commonly located on the substrate, or the driver IC is directly served as a substrate to carry the micro-LEDs to encapsulate them into a micro-LED module. The stretchable conductive material is used to be disposed on the flexible substrate, and the related control circuits are also encapsulated. Therefore, a stretchable display device which can be applied to a non-planar electronic device. It effectively reduces the problem of rising resistance caused by stretching.

Detailed descriptions are given below with specific embodiments and accompanied drawings, so that it is easier to understand the objective, technical content, characteristics and effects of the present invention.

### BRIEF DESCRIPTION OF THE DRAWINGS

FIG. 1 is a diagram illustrating a display device of the present invention.

FIGS. 2A-2C are diagrams illustrating a micro-LED module of the display device of a first embodiment of the present invention.

FIGS. 3A-3C are diagrams illustrating a micro-LED module of the display device of a second embodiment of the present invention.

FIG. 4 is a diagram illustrating a vertical micro-LED of the display device of the present invention.

FIGS. 5A-5C are diagrams illustrating a micro-LED module of the display device of a third embodiment of the present invention.

FIG. 6 is a diagram illustrating a same-plane contact of the vertical micro-LED and the driver IC bonding pad of the display device of the present invention.

FIGS. 7A-7C are diagrams illustrating a micro-LED module of the display device of a fourth embodiment of the present invention.

FIGS. 8A-8C are diagrams illustrating the driver layout of the micro-LED module of the display device of the present invention.

FIG. 9 is a diagram illustrating an equivalent circuit of the micro-LED module of the display device of the present invention.

### DETAILED DESCRIPTION OF THE INVENTION

The embodiments of the present invention will be further explained by following related drawings. As far as possible, in the drawings and description, the same reference numerals represent the same or similar components. For clarity concerns or to emphasize the technical features of the present invention, some parts or elements in the drawings, such as shape and thickness, may not be shown in the actual ratios. It can be understood that the elements that are not specifically shown in the drawings or described in the specification are in the form known to those skilled in the art. Those skilled in the art can make various changes and modifications based on the content of the present invention.

When an element is called “on”, it can generally mean that the element is directly on other elements, or there can be other elements existing in both. Conversely, when a component is called “directly in” another component, it cannot have other components in between. As used herein, the term “and/or” comprises any combination of one or more of the listed related items.

The following description of “one embodiment” or “an embodiment” refers to at least one specific element, structure, or feature related to the embodiment. Therefore, multiple descriptions of “one embodiment” or “an embodiment” appearing in various places below are not directed to the same embodiment. Furthermore, specific components, structures, and features in one or more embodiments can be combined in an appropriate manner.

Following examples are used to describe the present invention, but they are only for illustrative objectives. Those skilled in the art may readily observe that various modifications and alterations of the device and method may be made without departing from the spirit and the scope of the invention. Hence, the claimed scope of the present disclosure should be based on the claims defined hereinafter. Throughout the specification and claims, except for those further defined in the content, the meaning of the terms “a” and “the” may include the meaning of “one or at least one” element or component. Moreover, throughout the specification and claims, the singular terms may also refer to plural elements or components, unless the context clearly specifies that the plural usage is excluded. In the whole specification and claims, unless the content clearly specifies the meaning of some terms, the meaning of the term “wherein” comprises the meaning of in/on something/somewhere”. The meaning of each term used in the present claims and specification refers to a usual meaning known to one skilled in the art unless the meaning is additionally annotated. Some terms used to describe the present invention will be discussed to guide practitioners to realize the present invention. Further, various embodiments in the specification in are not meant to limit the claimed scope of the present invention.

In addition, the term “electrically coupled” can refer to either directly connections or indirectly connections between elements. Hence, if it is described in the contents of the present invention below that a first device is electrically coupled to a second device, the first device can be either directly connected to the second device, or indirectly connected to the second device through other devices or means. Moreover, as far as the transmissions or generations of electrical signals are mentioned, one skilled in the art should understand some degradations or unwanted transformations could be generated during the operations. However, if it is not specified in the specification, an electrical signal at the transmitting end should be viewed as substantially the same as that at the receiving end. For example, when the end A of an electrical circuit provides an electrical signal S to the end B of the electrical circuit, the voltage of the electrical signal S may drop due to passing through the source and drain of a transistor or due to some possible parasitic capacitance. However, the objective of this design is not meant to achieve some specific technical effects by deliberately using the degradation generated during the transmission. The electrical signals S at the end A should be viewed as substantially the same as that at the end B.

Furthermore, it can be understood that the terms “comprising,” “comprising,” “having,” “containing,” and “involving” are open-ended terms, which refer to “may include but is not limited to.” In addition, each of the embodiments or claims of the present invention is not necessary to achieve all possible advantages and features. Further, the abstract and title of the present invention is used to assist the patent searching, rather than limiting the claimed scope of the present invention.

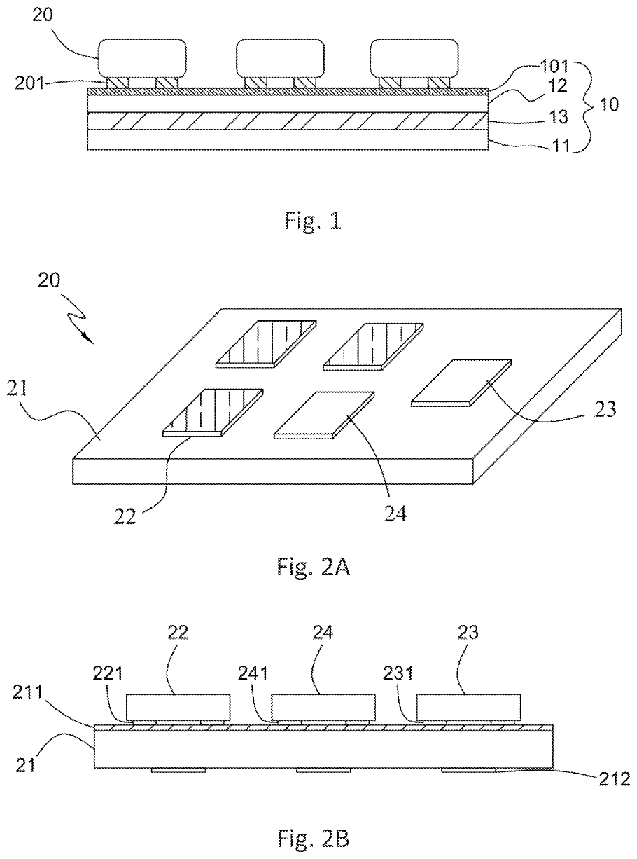

Please refer to FIG. 1, which is a schematic diagram of the display device of the present invention. The display device shown in FIG. 1 includes a flexible substrate 10 and a plurality of micro-LED modules 20. The micro-LED modules 20 are disposed on the stretchable conductive material 101 of the flexible substrate 10 through the bonding pad 201. The micro-LED modules 20 are connected in series via the layout of the stretchable conductive material 101 of the flexible substrate 10, thus it can be applied to non-planar electronic devices. The present invention is not limited to the above, however. Non-planar displays generally adopt thermoplastic molding. The flexible substrate 10 may include a film layer 12 and a formable film 11 disposed on the film layer 12. In other words, the film layer 12 may be adhered to the formable film 11 by the adhesive layer 13. The formable film 11 may be composed of polyethylene terephthalate, polycarbonate, acrylonitrile butadiene styrene, polyethylene naphthalate, polyolefin, polyethylene or cycloolefin polymer, and it is easy to be thermoformed. As to the film layer 12, it may be a polyimide film structure with circuitry. Certainly, the composition and materials of the above-mentioned flexible substrate 10 (the formable film 11 and the film layer 12) are merely for illustrative purposes. The present invention is not limited to these materials.

The material of the stretchable conductive material 101 is generally formed of electrically conductive metals such as gold, silver, copper, aluminum, molybdenum, or titanium with conductive adhesive. Therefore, the stretchable conductive material 101 is mainly gold, silver, copper, aluminum, molybdenum, titanium or the alloys thereof. The electrically conductive glue may be formed of a copper glue, a silver glue or the combinations thereof. Similarly, these materials are only examples of commonly seen electrically conductive materials, and are not used as limitations. Considering that the resistance of various stretchable conductive materials (e.g. the stretchable conductive material 101) is relatively high in other embodiments, the micro-LED and the driving circuit are integrated in the micro-LED module 20. That is, the related control circuits are all designed in the micro-LED module 20. Outside the micro-LED modules 20, the micro-LED modules 20 are connected in series via the layout of the stretchable conductive material 101 of the flexible substrate 10, and meanwhile is more applicable for non-planar display structures. Several structural embodiments of the micro-LED module 20 are illustrated below with reference to the drawings.

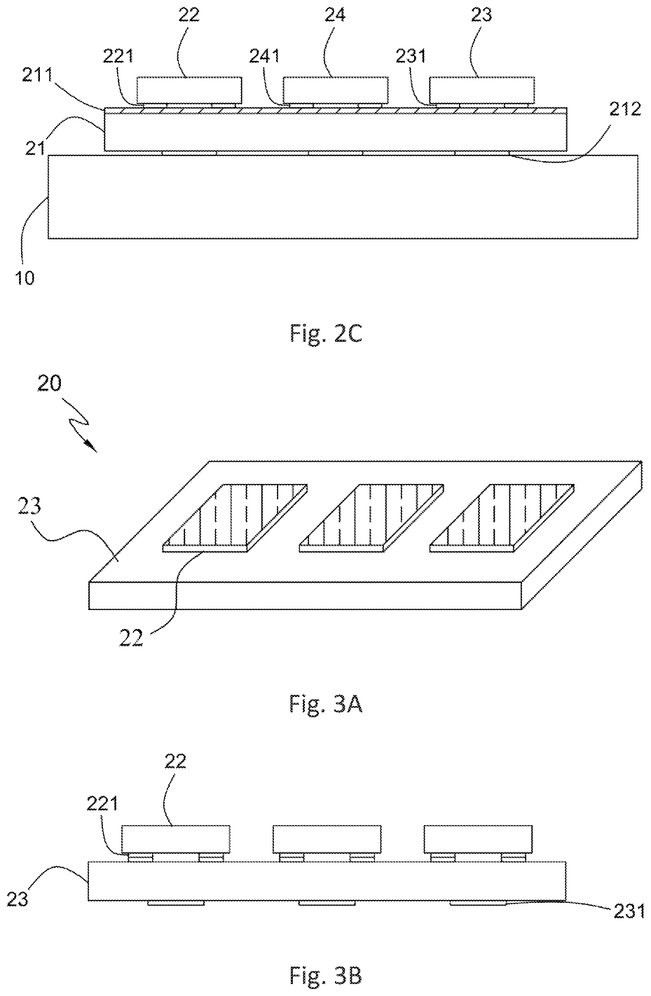

Please refer to FIGS. 2A-2C, which are diagrams illustrating a micro-LED module of the display device of a first embodiment of the present invention. In this embodiment, the micro-LED module 20 includes a substrate 21, at least one micro-LED 22 and a driver IC 23. A circuit layer 211 is formed on the substrate 21. The micro-LED 22 and the driver IC 23 are disposed thereon and form the electrical connection with the circuit layer 211 of the substrate 21. Generally speaking, the micro-LED 22 includes a red micro-LED, a green micro-LED or a blue micro-LED, and the material of the substrate 21 may be a glass, silicon, resin substrate, etc.

Specifically, the micro-LED 22 is disposed on the circuit layer 211 of the substrate 21 via the bonding pad 221, and forms an electrical connection with the circuit layer 211. The driver IC 23 is disposed on the circuit layer 211 of the substrate 21 via the driver IC bonding pad 231, and forms an electrical connection with the circuit layer 211. On the other hand, the substrate 21 further has a common cathode 24. The common cathode 24 is disposed on the circuit layer 211 of the substrate 21 through the bonding pad 241, and forms an electrical connection with the circuit layer 211. The common cathode 24 is connected to the cathodes of all the micro-LEDs 22 (through the circuit layer 211 of the substrate 21), and the micro-LEDs 22 can be driven by the anode.

There is at least one bonding pad 212 on another side of the substrate 21, i.e. the side of the substrate 21 other than the side that has the circuit layer 211, so that the substrate 21 is disposed on the stretchable conductive material 101 of the flexible substrate 10 (see FIG. 1). The side of the substrate 21 that has the circuit layer 211 forms an emission side.

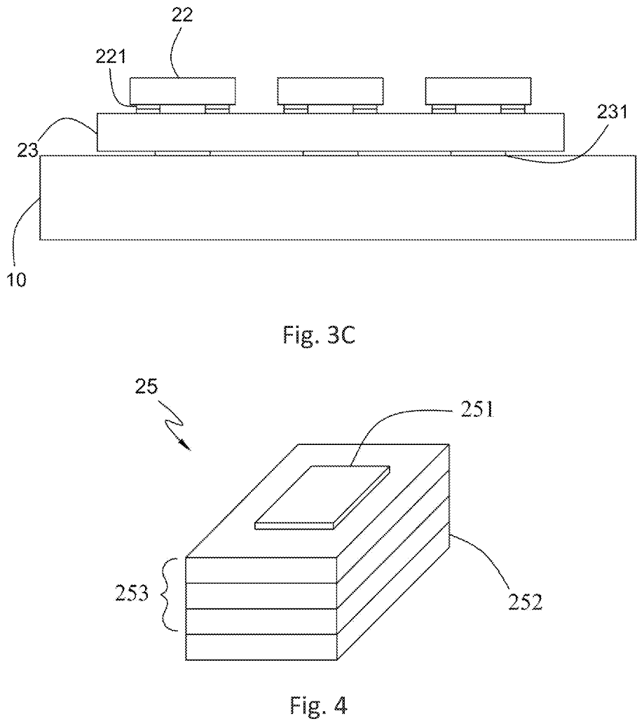

Next, please refer to FIGS. 3A-3C which are diagrams illustrating a micro-LED module of the display device of a second embodiment of the present invention. In this embodiment, the micro-LED module 20 includes a driver IC 23 and at least one micro-LED 22. The driver IC 23 allows the micro-LED 22 to be directly disposed thereon. That is, the driver IC 23 is served as a substrate (i.e. the ICs or chips required to be controlled and driven are integrated into the driver IC 23). The micro-LEDs 22 are directly disposed thereon and form an electrical connection therewith. Generally speaking, the micro-LED 22 includes a red micro-LED, a green micro-LED or a blue micro-LED.

Specifically, the micro-LED 22 is disposed on the driver IC 23 through the bonding pad 221, and forms an electrical connection with the driver IC 23. There is at least one driver IC bonding pad 231 on another side of the driver IC 23, i.e. the side of the driver IC 23 that is opposite to the micro-LED 22, so that the substrate is disposed on the stretchable conductive material 101 of the flexible substrate 10 (see FIG. 1). The upper side of the substrate 23 that has the micro-LED 22 forms an emission side. The through silicon via (TSV) technique may be utilized to connect the driver IC bonding pads 231 on both sides of the driver IC 23.

In addition to the flip-chip micro-LEDs used in the first and second embodiments described above, the vertical micro-LEDs can also be applied. Please refer to FIG. 4, which is a diagram illustrating a vertical micro-LED of the display device of the present invention. The vertical micro-LED 25 includes light-emitting layers 253, a metal electrode 251 on the uppermost light-emitting layer 253 and a metal electrode 251 under the bottommost light-emitting layer 253. Regarding the light-emitting layers 253, in a common example, it may include N-type nitrogen Gallium, an actuation material layer and P-type gallium nitride, etc. Although this part is described by using the structure of the common vertical micro-LED 25 in the figure, the present invention is not limited thereto.

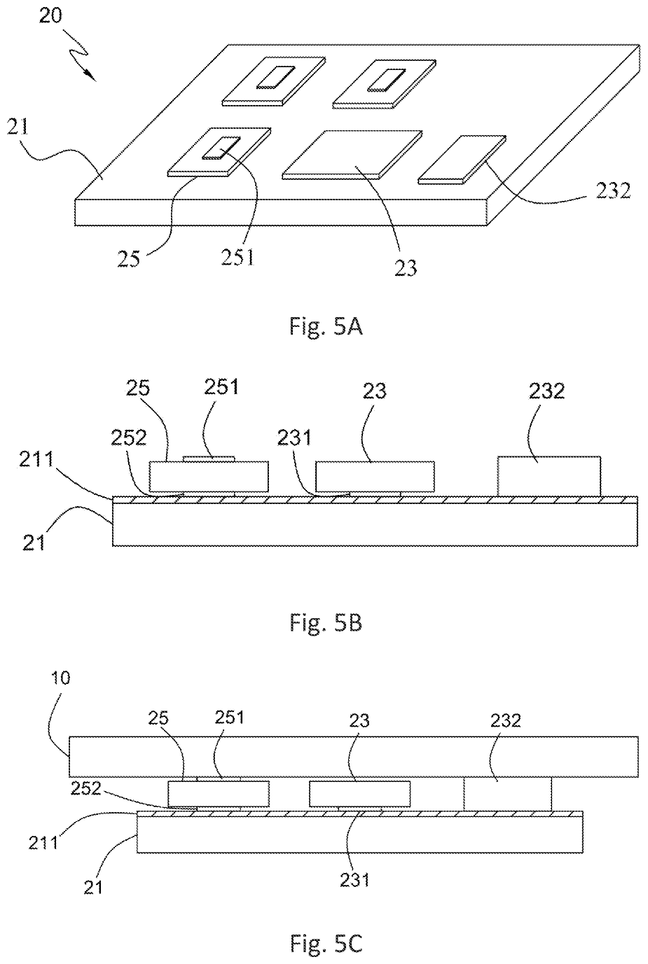

Please refer to FIGS. 5A-5C, which are diagrams illustrating a micro-LED module of the display device of a third embodiment of the present invention. In this embodiment, the micro-LED module 20 includes a substrate 21, at least one vertical micro-LED 25 and a driver IC 23. A circuit layer 211 is formed on the substrate 21, and the vertical micro-LED 25 and the driver IC 23 are disposed on the substrate 21 to form an electrical connection with the circuit layer 211 of the substrate 21. Generally speaking, the micro-LED 22 includes a red micro-LED, a green micro-LED or a blue micro-LED. The material of the substrate 21 can be glass, silicon or resin, etc.

Specifically, the vertical micro-LED 25 is disposed on the circuit layer 211 of the substrate 21 through the metal electrode 252 on the bottom, and forms an electrical connection with the circuit layer 211. The driver IC 23 is disposed on the circuit layer 211 of the substrate 21 via the driver IC bonding pad 231, and forms an electrical connection with the circuit layer 211. On the other hand, there is another driver IC bonding pad 232 formed on the substrate 21, so that the metal electrode 251 on the micro-LED 25 as well as the driver IC bonding pad 232 can be attached to the stretchable conductive material 101 of the flexible substrate 10 (see FIG. 1). The upper side of the substrate 21 (i.e. the side that has the circuit layer 211) is the emission side. Therefore, the flexible substrate 10 has to be a transparent substrate.

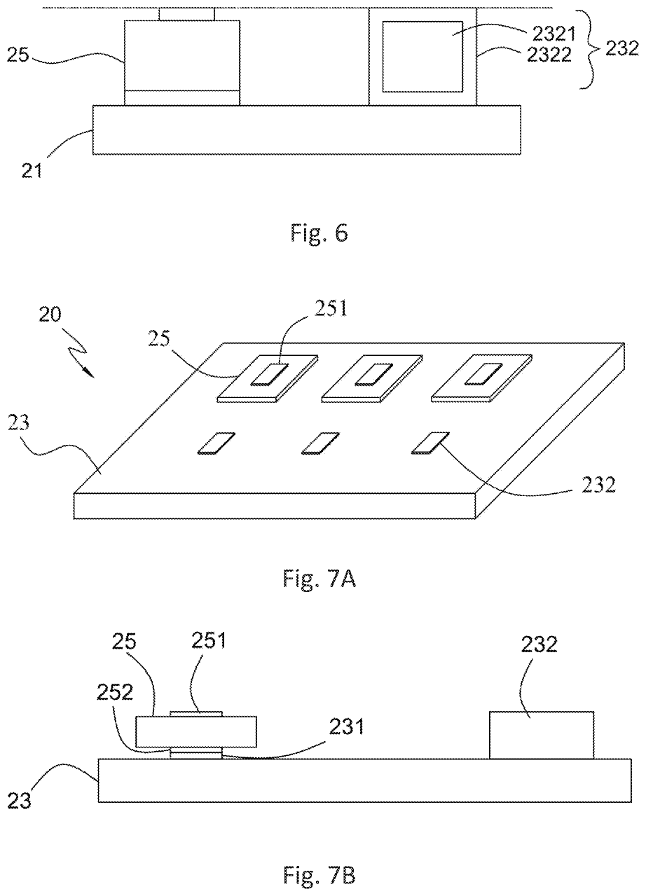

Next, please refer to FIG. 6 which is a diagram illustrating a same-plane contact of the vertical micro-LED and the driver IC bonding pad of the display device of the present invention. Because the micro-LED module 20 in the previous embodiments needs to be attached to the side of the flexible substrate 10 that has the stretchable conductive material 101, i.e. the metal electrode 251 on the vertical micro-LED 25 and the driver IC bonding pad 232 of the driver IC 23 needs to be attached to the stretchable conductive material 101 of the flexible substrate 10, an co-plan must be formed. That is, the height of the driver IC bonding pad 232 must be equal to the height of the micro-LED 25. Generally speaking, the height of the vertical micro-LED 25 is about 10 microns, and the common process of manufacturing the IC bonding pad 232 is to adopt the metal sputtering using the physical vapor deposition. Due to the inherent limitations of this process, it is generally difficult for the IC bonding pad 232 to reach this height (approximately 10 microns). Therefore, the driver IC bonding pad 232 is designed to be composed of a thickened material 2321 and a metal layer 2322 coating the thickened material 2321. The thickened material 2321 may be an electrically conductive glue or a photoresist material. In this way, all the electrodes on the substrate 21 are with the same height, and can be attached to the stretchable conductive material 101 of the flexible substrate 10 in a coplanar condition.

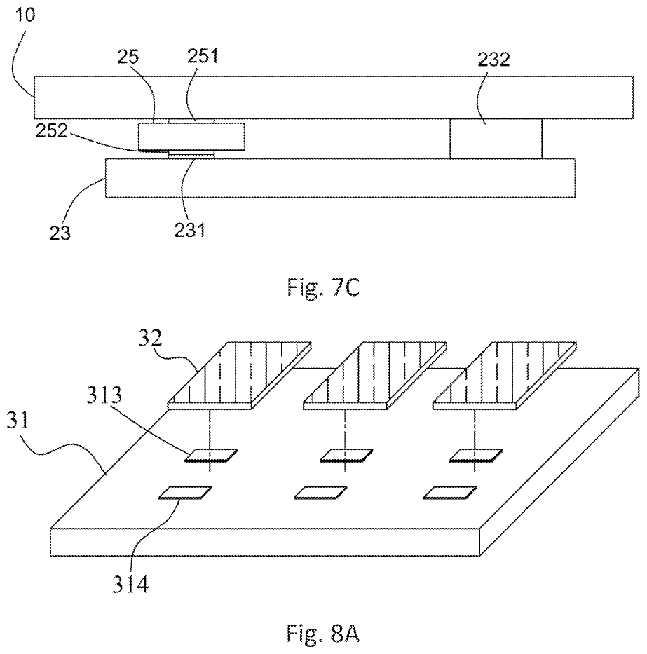

Please refer to FIGS. 7A-7C, which are diagrams illustrating a micro-LED module of the display device of a fourth embodiment of the present invention. In this embodiment, the micro-LED module 20 includes a driver IC 23 and at least one micro-LED (which is a vertical micro-LED 25 in this embodiment). The vertical micro-LEDs 25 are disposed on the driver IC 23, which means the driver IC 23 is served as a substrate (i.e. the ICs or chips that need to be controlled and driven are integrate into the form of the driver IC 23), so that the vertical micro-LED 25 may be directly disposed on the metal electrode 252 on the bottom and form an electrical connection with the metal electrode 252. Generally speaking, the micro-LED 22 includes a red micro-LED, a green micro-LED or a blue micro-LED.

Specifically, the vertical micro-LED 25 is disposed on the circuit layer 211 of the substrate 21 through the metal electrode 252 on the bottom, and forms an electrical connection with the circuit layer 211. On the other hand, the driver IC 23 includes the driver IC bonding pad 232 aside the vertical micro-LED 25 so as to align with the metal electrode 251 located above the vertical micro-LED 25. The stretchable conductive material 101 of the aforementioned flexible substrate 10 (See FIG. 1) can be disposed thereon and the upper side of the substrate 21 (i.e. the side of the substrate 21 that has the circuit layer 211) functions as the emission side. Therefore, the flexible substrate 10 has to be a transparent substrate.

Similarly, in order to carry out the same height coplanar bonding, the driver IC bonding pad 232 is composed of a thickened material 2321 coating by a metal layer 2322 (see FIG. 6). Since this part is the same as that mentioned in the previous embodiment, similar descriptions are omitted here for brevity.

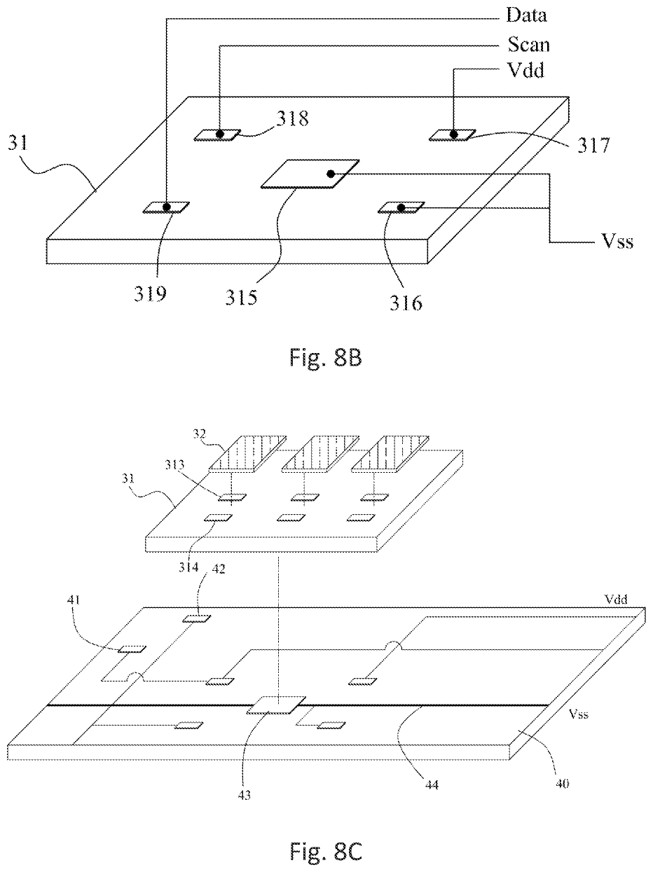

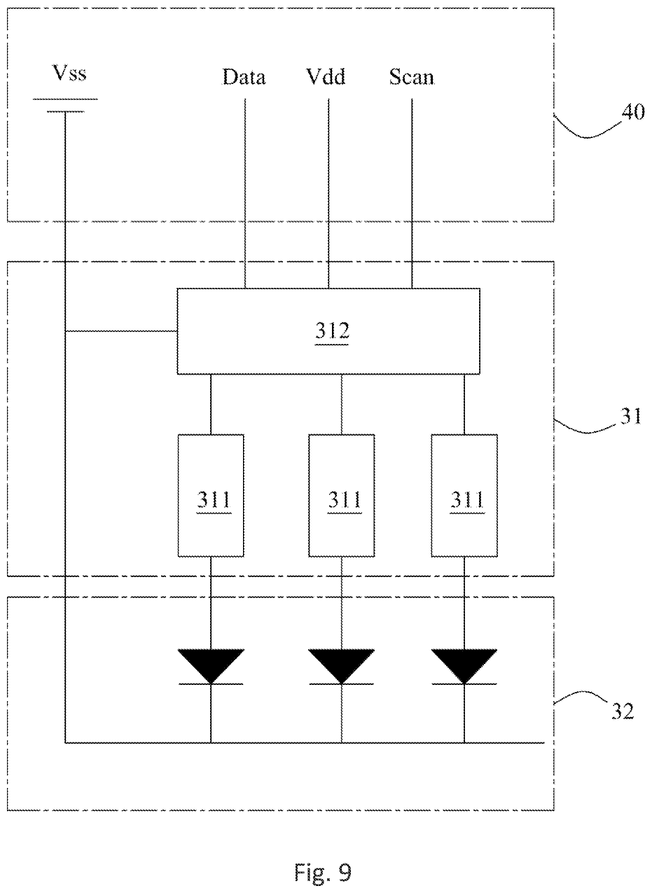

A practical example is given below to illustrate the circuit layout of the present invention. Please refer to FIGS. 8A-8C which are diagrams illustrating the driver layout of the micro-LED module of the display device of the present invention, as well as FIG. 9 which a diagram illustrating an equivalent circuit of the micro-LED module of the display device of the present invention. The driver IC 31 is used as a carrier substrate for arranging the micro-LED chip 32. As mentioned above, the micro-LED chip 32 includes a red micro-LED chip, a green micro-LED chip or a blue micro-LED chip. In the figure, it is only for illustrative purposes, and is not meant to limit the present invention to include only three micro-LED chips 32. The driver IC 31 integrates the micro-LED chip 32 as well as other circuits and elements for driving and controlling. In a most common case, the driver IC 31 may include a compensation circuit 311 and a micro control chip 312. Generally speaking, the currently existing control method is to use voltage or current to control the gray scale. However, the current is affected by various external factors and thus needs to be compensated. Examples of the external factors may include: thin film transistor (TFT) mobility, threshold voltage, enabling voltage variations, the amplitude of the driving voltage and power supply voltage of OLEDs, the power supply voltage drop, the drift of the light-emitting element threshold, etc. Those factors all need to be compensated by an external capacitor or inductance compensation technologies. Furthermore, if it is driven under constant voltage, a temperature compensation capacitor is further connected to provide stable luminous efficacy. As for the front side, because it is used for arranging the micro-LED chip 32, each location corresponding to a micro-LED chip 32 has an anode terminal 313 and a cathode terminal 314, so that the micro-LED chip 32 is connected to the driver IC 31 via the anode terminal 313 and the cathode terminal 314. In terms of the back side of the integrated circuit 31, it has a common cathode 315 and a ground voltage terminal 316, a driving operating voltage terminal 317, a driving scan line terminal 318, and a driving data line terminal 319. The common cathode 315 is connected to the cathode terminal 314 on the front side via the internal circuitry of the driver circuit 31, and is connected to the ground voltage Vss together with the ground voltage terminal 316. The driving voltage terminal 317 can receive the inputted working voltage Vdd, and the driving scan line terminal 318 and the driving data line terminal 319 can receive driving control signals, i.e., the driving scan signal Scan and the driving data signal Data, respectively.

The flexible substrate 40 has a driving scan chip 41 and a driving data chip 42, and also has a plurality of connection terminals 43 corresponding to the common cathode 315 and the ground voltage terminal 316, the driving voltage terminal 317, the driving scan line terminal 318 and the driving data line terminal 319, so that the driver IC 31 can be disposed thereon and the connection wire 44 can adopt the stretchable conductive material in order to perform wiring layout. In other words, in addition to the inherent controlling capabilities (such as the pulse width modulation, pulse amplitude modulation, etc.), the flexible substrate 40 further integrate complex thin film transistor circuits. Therefore, the driver IC 31 and the micro-LED chip 32 thereon may form a micro-LED module, which can be connected in series onto the flexible substrate 40. Further, the related driving control circuits are all integrated in the driver IC 31, so that the driving scan chip 41 and a driving data chip 42 or other required control chips can be directly used to control each micro-LED chip 32.

The display device provided by the present invention integrates a driver IC and micro-LEDs into a micro-LED module. The driver IC and the micro-LEDs are commonly located on the substrate, or the driver IC is served as a substrate to carry the micro-LEDs and encapsulate them into the micro-LED module. The stretchable conductive material is further used to arrange the micro-LED module on the flexible substrate, so as to encapsulate the related control circuits. Further, the stretchable display device is formed and can be applied to a non-planar electronic device, thereby effectively reducing the problem of rising resistances caused by stretching.

The above-mentioned embodiments are only to illustrate the technical ideas and features of the present invention. The objective is to make one skilled in the art able to understand and implement the content of the present invention, rather than limiting the scope of the present invention. That is, all equal changes or modifications made according to the spirit of the present invention shall fall within the scope of the present invention.

What is claimed is:

1. A display device, comprising:
a flexible substrate; and
a plurality of micro light-emitting diode (LED) modules, disposed on one side of the flexible substrate via a stretchable conductive material, and each of the micro-LED modules comprising:
at least one substrate, having a circuit layer disposed thereon;
at least one micro-LED, disposed on the circuit layer of the substrate and forming an electrical connection with the circuit layer; and
a driver integrated circuit (IC), disposed on the circuit layer of the substrate and forming an electrical connection with the circuit layer.

2. The display device according to claim 1, wherein the micro-LED is a red micro-LED, a green micro-LED or a blue micro-LED.

3. The display device according to claim 1, wherein the flexible substrate comprises a thin film layer and a formable film disposed on the thin film layer.

4. The display device according to claim 1, wherein the stretchable conductive material is composed of an electrically conductive metal, an electrically conductive glue, or a combination thereof.

5. The display device according to claim 1, wherein the micro-LED module further comprises a common cathode, disposed on the circuit layer of the substrate and forming an electrical connection with the circuit layer.

6. The display device of claim 1, wherein the micro-LED is disposed on the circuit layer of the substrate via a bonding pad, and forms an electrical connection with the circuit layer.

7. The display device according to claim 1, wherein another side of the substrate has at least one bonding pad disposed on the stretchable conductive material of the flexible substrate, and makes the side of the circuit layer of the substrate be an emission side.

8. The display device of claim 1, wherein the micro-LED is a vertical micro-LED, and each of two sides of the vertical micro-LED has a metal electrode, and wherein the vertical micro-LED is disposed on the circuit layer of the substrate via one of the metal electrodes to form an electrical connection with the circuit layer.

9. The display device according to claim 8, wherein the micro-LED module further comprises a driver IC bonding pad, and the driver IC bonding pad is disposed on the circuit layer of the substrate and is electrically connected to the circuit layer and the driver IC.

10. The display device according to claim 9, wherein the driver IC comprises another driver IC bonding pad to be disposed on the stretchable conductive material of the flexible substrate, and the other metal electrode of the vertical micro-LED is disposed on the stretchable conductive material of the flexible substrate.

11. The display device according to claim 10, wherein the flexible substrate is a transparent substrate to serve as an emission side.

12. The display device according to claim 9, wherein the driver IC bonding pad is formed by coating a metal layer on a thickened material.

13. The display device according to claim 12, wherein the thickened material is an electrically conductive glue or a photoresist material.

14. A display device, comprising:
a flexible substrate; and
a plurality of micro-LED modules, disposed on one side of the flexible substrate via a stretchable conductive material, wherein each of the micro-LED modules comprises:
at least one driver integrated circuit (IC); and
at least one micro-LED, disposed on the driver IC and electrically connected to the driver IC.

15. The display device according to claim 14, wherein the micro-LED is a red micro-LED, a green micro-LED or a blue micro-LED.

16. The display device according to claim 14, wherein the flexible substrate comprises a thin film layer and a formable film disposed on the thin film layer.

17. The display device according to claim 14, wherein the stretchable conductive material is composed of an electrically conductive metal, an electrically conductive glue or a combination thereof.

18. The display device according to claim 14, wherein the micro-LED is disposed on a bonding pad of the driver IC via a bonding pad to form an electrical connection with the driver IC.

19. The display device according to claim 18, wherein another side of the driver IC has at least one bonding pad disposed on the stretchable conductive material of the flexible substrate.

20. The display device according to claim 14, wherein the micro-LED is a vertical micro-LED, and each of two sides of the vertical micro-LED has a metal electrode, and wherein the vertical micro-LED is disposed on a bonding pad of the driver IC via one of the metal electrodes to form an electrical connection with the driver IC.

21. The display device according to claim 20, wherein the driver IC has a driver IC bonding pad disposed thereon to form an electrical connection with the driver IC.

22. The display device according to claim 21, wherein the driver IC comprises another driver IC bonding pad to be disposed on the stretchable conductive material of the flexible substrate, and the other metal electrode of the vertical micro-LED is disposed on the stretchable conductive material of the flexible substrate.

23. The display device according to claim 22, wherein the flexible substrate is a transparent substrate to serve as an emission side.

24. The display device according to claim 21, wherein the driver IC bonding pad is formed by coating a metal layer on a thickened material.

25. The display device according to claim 24, wherein the thickened material is an electrically conductive glue or a photoresist material.
